(19) United States
(12) Patent Application Publication
(10) Pub. No.: US 2026/0276701 A1
(43) Pub. Date: Sep. 17, 2026

(54) TESTING DEVICE AND METHOD FOR TESTING AN ELECTRONIC DEVICE

(71) Applicant: JCET STATS ChipPAC Korea Limited, Incheon (KR)

(72) Inventors: MyungKi KIM, Incheon (KR); SeokJin LEE, Gyeonggi-do (KR); MinJun KIM, Gyeonggi-do (KR)

(21) Appl. No.: 19/562,843

(22) Filed: Mar. 11, 2026

(30) Foreign Application Priority Data
Mar. 11, 2025 (CN) 202510284883.1

(51) Int. Cl. G01R 31/28; G01R 1/04; G01R 1/067

(52) U.S. Cl. CPC G01R 31/2887; G01R 1/0466; G01R 1/06772; G01R 31/2853; G01R 31/2884; G01R 31/2889; G01R 31/2891

(57) ABSTRACT

A testing device and a method for testing an electronic device are provided. The electronic device comprises a socket board, a plurality of contact pads and a socket unit on the socket board. The testing device comprises a Sub Miniature version A (SMA) probe connector and a lid body comprising a conductive portion, an escape groove and an opening. The conductive portion is connected to the contact pins of the socket unit aligned with ground contact pads, the escape groove accommodates contact pins of the socket unit aligned with the signal contact pad, and the opening is aligned with and connected to the escape groove when connecting the testing device to the socket unit. A conductive housing of the SMA probe connector is electrically connected with the conductive portion of the lid body and extend a signal probe of the SMA probe connector through the opening and the escape groove.

### TECHNICAL FIELD

The present application generally relates to testing technology, and more particularly, to a testing device and a method for testing an electronic device.

### BACKGROUND OF THE INVENTION

The semiconductor industry is constantly faced with complex integration challenges as consumers want their electronics to be smaller, faster and higher performance with more and more functionalities packed into a single device. Electronic components that have undergone complicated processing are subject to various types of electrical tests for testing their characteristics and for identifying their potential defects.

To this end, a testing socket is used to electrically connect metallic wires or contact pads of a socket board (for example, a printed circuit board) mounted in testing equipment with connectors or terminals of an electronic component to be tested. That is, when an electronic component is being tested, the testing socket serves as an interface to electrically connect the socket board of the testing equipment with the electronic component under test. Establishing the connection between the testing equipment and the electronic component under test may induce a path loss that results in deterioration of the device performance, especially when the electronic component is tested by high frequency signals. Thus, the path loss should be calibrated from test results of the electronic component to remove the deterioration of the device performance that occurs during the testing process, and improve accuracy of the test results. However, it is difficult to measure the path loss induced by the test socket and the socket board conveniently by using the existing testing device.

Therefore, a need exists for a testing device and a method for testing an electronic device.

### SUMMARY OF THE INVENTION

An objective of the present application is to provide a testing device and a method for testing an electronic device.

According to an aspect of the present application, a testing device for testing an electronic device. The electronic device comprises a socket board, a plurality of contact pads on the socket board, and a socket unit mounted on the socket board, wherein the plurality of contact pads comprise multiple ground contact pads and a signal contact pad, and wherein the socket unit comprises a socket body and a plurality of contact pins vertically extending through the socket body and each being aligned with and operably connected to one of the plurality of contact pads. The testing device is operably connected to the electronic device. The testing device comprises: a lid body comprising: a conductive portion disposed at a center of the lid body and configured to be connected to the contact pins of the socket unit that are aligned with the ground contact pads when the testing device is connected to the socket unit; an escape groove formed at a first side of the conductive portion facing towards the plurality of contact pins, and configured to accommodate the contact pins of the socket unit aligned with the signal contact pad to avoid contact with the conductive portion when the testing device is connected to the socket unit; and an opening formed at a second side of the conductive portion facing away from the plurality of contact pins, wherein the opening is aligned with and connected to the escape groove; and a Sub Miniature version A (SMA) probe connector mounted on the lid body, to electrically connect a conductive housing of the SMA probe connector with the conductive portion of the lid body and extend a signal probe of the SMA probe connector through the opening and the escape groove, wherein the SMA probe connector is configured to electrically connect the signal probe with a contact pin of the socket unit aligned with the signal contact pad when the testing device is connected to the socket unit.

According to another aspect of the present application, a testing method is provided. The electronic device comprises a socket board, a plurality of contact pads on the socket board, and a socket unit mounted on the socket board; wherein the plurality of contact pads comprise multiple ground contact pads and a signal contact pad; wherein the socket board comprises a reference connector mounted on the socket board; wherein the socket unit comprises a socket body and a plurality of contact pins vertically extending through the socket body and each being aligned with and operably connected to one of the plurality of contact pads. The testing device is operably connected to the electronic device. The testing method comprises: mounting a SMA probe connector on a lid body to electrically connect a conductive housing of the SMA probe connector with a conductive portion at a center of the lid body and pass a signal probe of the SMA probe connector through an opening formed at a second side of the conductive portion facing away from the plurality of contact pins and an escape groove at a first side of the conductive portion facing towards the plurality of contact pins, such that the signal probe is electrically connected with a contact pin of the socket unit aligned with the signal contact pad; connecting the lid body to the socket unit to connect the conductive portion of the lid body with contact pins of the socket unit that are aligned with the ground contact pads, and to accommodate contact pins of the socket unit aligned with the signal contact pad to avoid contact between a contact pin and the conductive portion by the escape groove; and connecting a first signal cable coupled to the SMA probe connector and a second signal cable coupled to the reference connector of the socket board to a signal measurement instrument, to enable testing of the electronic device by the signal measurement instrument through the testing device.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a testing device for testing an electronic device according to a first embodiment of the present application.

FIG. 1B illustrates a top view of a socket unit of the electronic device in FIG. 1A.

FIG. 1C illustrates an exemplary layout of contact pads of a socket board of the electronic device in FIG. 1A.

FIG. 1D illustrates a SMA probe connector of the testing device in FIG. 1A.

FIG. 2 illustrates various steps of a method for testing an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic component is being tested by a testing device including a testing socket and a socket board, a path loss may be inevitably induced into test results generated by the testing apparatus. To be more specific, the testing socket may include pogo pins or similar connection components which help establish electrical connections between the electronic component and the socket board to test the electronic component. During this testing process, the path losses induced by the pogo pins and other connection components in signaling paths may inevitably occur and be incorporated within a test result of the electronic component. Therefore, it is desired to remove the path loss from the test result, so as to improve accuracy of the test result of the electronic component. However, it is difficult to accurately and conveniently measure path losses using conventional test apparatuses.

Some solutions have been provided to measure path losses of pogo pins. For example, a simulation of the path loss, or a pre-measured result of the path loss provided by pogo pin vendors may be used for calibration of a test result of an electronic component under test, instead of an actual measurement of the path loss when the electronic component is being tested. However, since this calibration information which is generated or measured beforehand is obtained in environments different from an actual testing environment of the electronic component, the accuracy of the calibration information of the path loss may still be unsatisfactory. In addition, when the path loss is measured beforehand, probes are generally used for connecting the pogo pins to measure the path losses. However, this measuring process may suffer from several issues such as poor contact reliability and deficient probe durability.

To address the above issues, a testing device and a method for testing an electronic device such as a socket are provided by the present application. The electronic device is used for testing electronic components such as semiconductor chips, semiconductor packages, or similar components. The electronic device includes a socket unit for accommodating the electronic component(s). The testing device and method provided by the present application can be used to test and calibrate this kind of electronic devices, avoiding or eliminating errors in the testing of electronic components. The testing device can be connected to the socket unit using an SMA (SubMiniature version A) probe connector, and a dedicated lid body is used for electrically connecting the SMA probe connector to the electronic device to be tested.

During testing, the testing device is connected to the socket unit of the electronic device, a conductive portion of the lid body disposed at the testing device is connected to contact pins that are aligned with ground contact pads, while an escape groove of the lid body accommodates a contact pin aligned with a signal contact pad to avoid its contact with the conductive portion, and a signal probe of the SMA probe connector is connected to the contact pin accommodated in the escape groove. That is, the contact pins aligned with the ground contact pads are grounded via the conductive portion of the lid body, while the contact pin aligned with the signal contact pad is connected to the SMA probe connector for allow signal transmission through the SMA probe. In this way, the testing device can be reliably and conveniently connected to the socket unit of the electronic device, thus improving the accuracy of testing results generated by the electronic device.

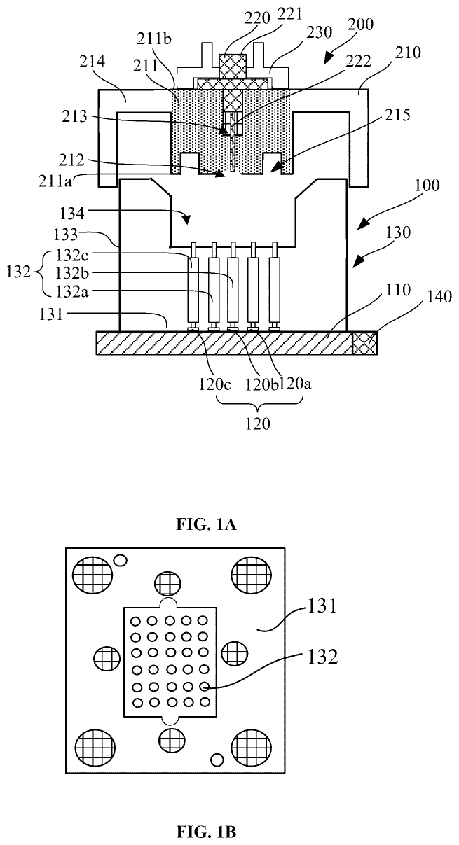

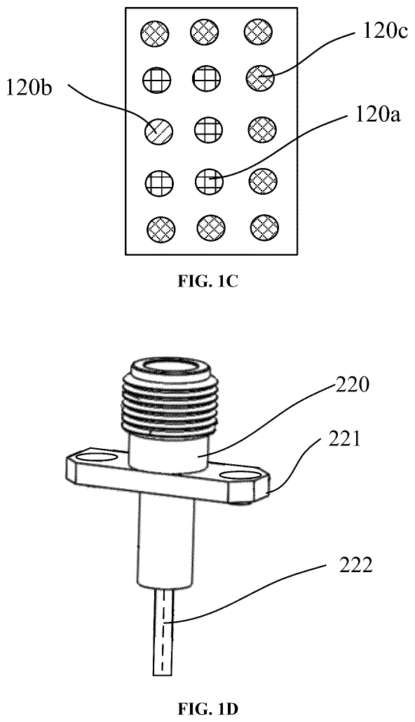

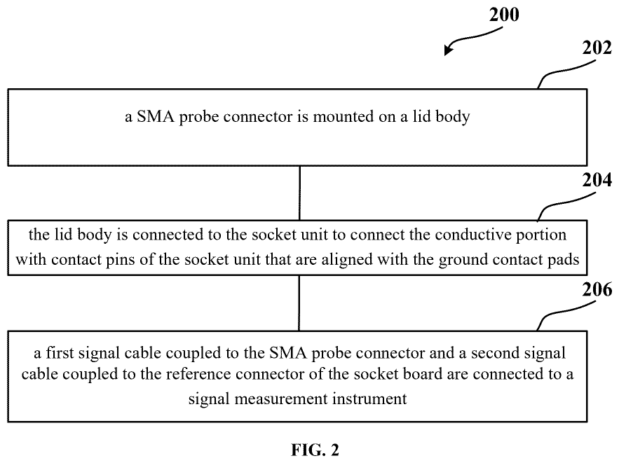

FIG. 1A illustrates a testing device 200 for testing an electronic device 100 according to a first embodiment of the present application. The electronic device 100 can be a device used for testing electronic components, for example, the electronic device 100 can be a socket. FIG. 1B illustrates a top view of a socket unit of the electronic device 100 in FIG. 1A. As shown in FIGS. 1A and 1B, the electronic device 100 includes a socket board 110, a plurality of contact pads 120, a socket unit 130 mounted on the socket board 110, one or more reference connector 140, and signal lines (not shown) which may be distributed within the socket board 110, for example, to connect the contact pads 120 to measurement modules mounted on or otherwise connected to the socket board 110, or to the reference connectors 140. In some embodiments, the reference connector 140 can be an SMA probe connector or other similar connectors. The SMA probe connector is a connector commonly used for radio-frequency (RF) and microwave applications, primarily for detection, transmission, and connection of high-frequency electronic signals. The SMA probe connector typically consists of an SMA interface section and a probe section. The SMA interface section features a standard threaded structure to ensure stable and reliable connections, particularly in high-frequency signals to maintain good electrical performance. The probe section is used to directly contact an object under test and is usually made of a metal material with good conductivity and elasticity to ensure a reliable connection with the object under test. Furthermore, the probe can have a shape which may vary, for example, the probe can be straight, bent, or claw-shaped, to suit different testing environments and different shapes of the object under test.

In some embodiments, the socket board 110 can serve as the base of the electronic device 100. The electronic component under test can be electrically connected to the socket board 110 via a plurality of contact pins 132 of the socket unit 130 when the electronic component is being tested. Thus, the electronic component can receive power, control signals or drive signals from the socket board 110, or send test results or data back to the socket board 110. Additionally, the socket board 110 can also be connected to an external testing equipment, such as a multimeter, which may or may not include a signal generator for testing the electronic components.

As illustrated in FIG. 1A, the plurality of contact pads 120 on the socket board 110 may include multiple ground contact pads 120a, a signal contact pad 120b, and one or more non-target contact pads 120c based on the signals transmitted in the signal lines connected to the plurality of contact pads 120 in the socket board 110. It should be noted that in this embodiment, only one signal contact pad 120b or its relevant path loss is needed to be tested by the testing device 200, which can be called as a target signal contact pad while the other signal contact pads may be called as non-target signal contact pads. However, in some other embodiments, multiple signal contact pads 120b may need to be tested, either simultaneously by a single testing device with multiple SMA probe connectors or by a set of testing devices each having a single SMA probe connector like the testing device shown in FIG. 1A. The ground contact pads 120a are conductive contact pads that are grounded during testing, while the signal contact pads 120b and 120c are conductive contact pads for transmitting electronic signals, where the signal contact pads 120b are the ones to be tested by the testing device 200, and the non-target contact pads 120c are the other ones that does not need to be tested by the testing device 200.

FIG. 1C illustrates an exemplary layout of the contact pads 120 of the socket board 110 of the electronic device 100 in FIG. 1A. As illustrated in FIGS. 1A and 1C, the signal contact pad 120b may be disposed at a center of the layout of the contact pads, while multiple ground contact pads 120a are disposed around the signal contact pad 120b, and the one or more non-target contact pads 120c are disposed around the multiple ground contact pads 120a. It can be appreciated that the layout of the plurality of contact pads may vary in other embodiments. For example, the signal contact pad 120b can be disposed at the center of the layout, the non-target contact pads 120c can be disposed around the one or more signal contact pads 120b, and the ground contact pads 120a can be disposed around the non-target contact pads 120c. One of the signal contact pads 120b can be connected to the testing device 200 when the electronic device 100 is being tested by the testing device 200.

Still referring to FIGS. 1A and 1B, the socket unit 130 includes a socket body 131 and a plurality of contact pins 132 vertically extending through the socket body 131. Each of the contact pin 132 is aligned with and operably connected to one of the plurality of contact pads 120. In some embodiments, each contact pin 132 being operably connected to one of the plurality of contact pads 120 means that the contact pins 132 and the contact pads 120 are connected in a way that enables signal transmission, control, or function implementation when the electronic component or the testing device 200 is mounted on the socket unit 130 because a certain pressing force can be applied to the contact pins 132 to move them downward towards the contact pads 120. However, the contact pins 132 can be separated from the contact pads 120 and not connected to each other when the electronic components or the testing device 200 are not mounted, i.e., when removed. In particular, the socket body 131 can include a vertical portion extending perpendicular to the socket board 110. The socket body 131 also includes a sidewall 133 at a periphery of the socket body 131 and a cavity 134 formed within the sidewall 133. The cavity 134 is used to accommodate the electronic components or the testing device 200. Additionally, the cavity 134 can include at its top a device loading opening connected to the inside of the cavity 134 to allow the electronic components or the testing device 200 to be received by the cavity 134 through the device loading opening. The cavity 134 can also include a guide member disposed at the device loading opening, which is used to guide the electronic components or the testing device 200 to move to a predetermined testing position within the cavity 134. The guide member can include one or more inclined surfaces.

It is understood that, during the actual testing, operational errors may occur when the electronic components or the testing device 200 is placed into the cavity 134, resulting in improper positioning of the electronic components or the testing device 200 which may affect the test results. However, by forming the guide member within the cavity 134, even if there is a certain degree of deviation in alignment of position when the electronic components or the testing device 200 is placed into the cavity 134, the guide member can guide the electronic components or the testing device 200 to move to the predetermined test position The accuracy of the testing is thus ensured.

In some embodiments, the contact pins 132 can have the same structure. For example, the contact pins 132 can include pogo pins. Each pogo pin 132 includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with a top contactor at its top end, and can be in contact with a bottom contactor at its bottom end. As such, the pogo pins 132 can be movable vertically relative to the socket body 131 with the coil spring providing an elastic connection between the electronic components or the testing device 200 and the socket board 110. With these configurations, the top contactors of the pogo pins 132 can be in contact with the conductive pads of the electronic components or the testing device 200, and the bottom contactors of the pogo pins 132 can be in contact with the contact pads 120 on the socket board when the top contactors of the pogo pins 132 are pressed by the electronic components or the testing device 200. Additionally, the top contactors and the bottom contactors are exposed from the front surface and the back surface of the socket body 131. In this way, the contact pin 132 may be pressed against the socket board 110 to set up a reliable electrical connection between the electronic components or the testing device 200 and the socket board 110, thereby creating a testing environment or system to test the electronic components or to be tested by testing device 200 (during calibration). In some other embodiments, the contact pins 132 can include other types of elastic connectors, such as elastic conductive posts.

In some embodiments, a signaling trace extends between the signal contact pad 120b and the reference connector 140 which are electrically coupled with each other, thus enabling signal transmission between the signal contact pad 120b and the reference connector 140. In some embodiments, the signaling trace can be a high-frequency (RF) trace. The signaling trace is designed to transmit RF signals, typically used to guide signals to a desired location or to measure impedance. In the case of multiple signal contact pads, for each signal contact pad 120b, there is a signaling trace extends between each signal contact pad 120b and the reference connector 140.

As shown in FIG. 1A, the testing device 200 includes a lid body 210, an SMA probe connector 220, and a positioning assembly 230 which can fix the SMA probe connector 220 to the lid body 210. The lid body 210 includes a conductive portion 211, an escape groove 212, an opening 213, a peripheral portion 214, and one or more additional escape grooves 215 which are optional in some embodiments. In this embodiment, the testing device 200 is described by taking the case where there is only one escape groove as an example. In some embodiments, when there is only one signal contact pad 120b, the measurement of the contact pin aligned with the signal contact pad can be completed through a single measurement. In some other embodiments, when there are multiple signal contact pads 120b, only contact pin aligned with one signal contact pad can be measured each time. Therefore, the measurement of the contact pins aligned with multiple signal contact pads can be completed by multiple measurements, and each measurement may be conducted using one of a set of testing devices.

In some embodiments, the conductive portion 211 is disposed at a center of the lid body 210, and includes a first side 211a facing towards the plurality of contact pins 132 and a second side 211b facing away from the plurality of contact pins 132. The conductive portion 211 is made of conductive materials (e.g., copper or aluminum or alloys thereof). The conductive portion 211 can be electrically connected to the contact pins 132 when they are in contact with each other. The peripheral portion 214 is connected to the conductive portion 211. In some embodiments, the material of the peripheral portion 214 can either be the same as or different from that of the conductive portion 211. When the material of the peripheral portion 214 is conductive, the portion of socket body 131 that contacts the peripheral portion 214 should be made of an insulating material to ensure electrical isolation.

In some embodiments, the escape groove 212 and the one or more additional escape grooves 215 are formed at the first side 211a of the conductive portion 211 which is the side of the conductive portion 211 facing towards the socket unit 130. In contrast, the opening 213 is formed at the second side 211b of the conductive portion 211. The opening 213 is aligned with and connected to the escape groove 212, thereby forming a continuous space. Both the escape groove 212 and the one or more additional escape grooves 215 are designed to accommodate the contact pins 132 aligned with the escape groove 212 and the one or more additional escape grooves 215. The depths of the escape groove 212 and the one or more additional escape groove 215 can either be the same or different.

As shown in FIGS. 1A and 1D, in some embodiments, the SMA probe connector 220 includes a conductive housing 221 and a signal probe 222, which are electrically isolated from each other by an internal insulating structure of the SMA probe connector 220. The conductive housing 221 is connected with the conductive portion 211 of the lid body 210 when the SMA probe connector 220 is mounted on the lid body 210, and the signal probe 222 extends through the opening 213 and the escape groove 212. As such, the signal probe 222 can be electrically connected to a contact pin aligned with the signal probe 222.

The testing device 200 is operably connected to the electronic device 100. Specifically during testing, the testing device 200 can be connected to the socket unit 130. In this situation, the peripheral portion 214 of the lid body 210 can support the entire structure of the testing device 200 on the socket unit 130. Specifically, the peripheral portion 214 is supported on the sidewall 134 of the socket body 131, the conductive portion 211 is received within the cavity 134 and is connected to the contact pins 132a of the socket unit 130 that are aligned with the ground contact pads 120a, and the escape groove 212 accommodates the contact pin 132b of the socket unit 130 aligned with the signal contact pad 120b to avoid its contact with the conductive portion 211. Similarly to the escape groove 212, the one or more additional escape grooves 215 can accommodate the contact pins 132c of the socket unit 130 aligned with the one or more non-target contact pads 120c to avoid contact between the one or more non-target contact pads 120c and the conductive portion 211. It can be understood that the number, location, and layout of the one or more additional escape grooves 215 can be set or adjusted according to the electronic device 100 being tested, particularly the distribution of contact pads and contact pins of the electronic device 100. It can also be understood that generally the bottom surface of the cavity 134 in the socket unit 130 is flat. In order to match and be connected to the socket unit 130, the bottom surface of the conductive portion 211 is typically flat as well, with the escape groove 212 and the additional escape groove 215 being recessed inward from the bottom surface of the conductive portion 211, so as to not affect the overall flatness of the bottom surface of the conductive portion 211.

When the electronic device 100 is being tested for path loss or other characteristics, the testing device 200 is electrically connected to the socket board 110 via the contact pins 132. The contact pins 132a aligned with the ground contact pads 120a can be electrically connected to the conductive portion 211. The top contactor of the pogo pin 132b aligned with the signal contact pad 120b can be electrically connected to the signal probe 222, while the bottom contactor of the pogo pin 132b aligned with the signal contact pad 120b is electrically connected to the contact pad 120b on the socket board 110. Thus, the contact pins 132 is pressed against the socket board 110 to establish a reliable electrical connection between the testing device 200 and the socket board 110.

In some embodiments, to reduce friction between the conductive portion 211 and the socket body 131 and to better guide the conductive portion 211 to slide into the cavity 134 of the socket unit 130, the conductive portion 211 is chamfered at its bottom edge, which is not shown.

The positioning assembly 230 is mounted at the second side 211b of the conductive portion 211 to fix the SMA probe connector 220, which is also mounted on the second side 211b, to the conductive portion 211. Specifically, the conductive housing 221 of the SMA probe connector 220 may have a flange structure extending outward from the body of the connector, and the positioning assembly 230 can form a gap with the top surface of the conductive portion 211 to accommodate and fix the flange structure to prohibit undesired movement of the SMA probe connector 220. Additionally, the signal probe 222 of the SMA probe connector 220 and the portion of conductive housing 221 surrounding the signal probe 222 can be embedded in the socket 213.

When the testing device 200 is connected to the socket unit 130, the positioning assembly 230 can adjust a distance between the lid body 210 and the plurality of contact pins 132, ensuring that the conductive portion 211 is pressed against the contact pins 132a of the socket unit 130 aligned with the ground contact pads 120a. In this case, the contact pin 132b of the socket unit 130 aligned with the signal contact pad 120b extends through the escape groove 212 and makes reliable contact with the signal probe 222 of the SMA probe connector 220 to avoid its contact with the conductive portion 211. The contact pins 132c of the socket unit 130 aligned with one or more non-target contact pads 120c are accommodated in the one or more additional escape grooves 215 to avoid their contact with the conductive portion 211. Conversely, the positioning assembly 230 can be used to increase the distance between the lid body 210 and the contact pins 132 to reduce a force applied by the conductive portion 211 when a too small distance results in a significant force applied to the contact pins 132 and the contact pads 120 by the lid body 210.

In some embodiments, the positioning assembly 230 can be fixedly coupled to the SMA probe connector 220 to form a component that can be connected to different types of lid bodies to form different types of testing devices, which can be used to measure different types of electronic devices. In this way, reuse of the positioning assembly 230 and the SMA probe connector 220 is achieved, and testing cost is reduced.

In some embodiments, the testing device can further include a test module which is not shown. The test module generates a test result by measuring an electrical characteristic associated with a test path between the reference connector 140 and the SMA probe connector 220 which are electrically coupled with each other by the plurality of contact pins 132 when the testing device 200 is connected to the socket unit 130. The test path extends from the SMA probe connector 220, passes through the contact pins 132 and the signaling trace on the socket board 110, eventually reaches the reference connector 140. The test module can be electrically connected to the SMA probe connector 220 and the reference connector 140. In some embodiments, the test module can be a Vector Network Analyzer (VNA). The SMA probe connector 220 can be connected to the first VNA port via an RF cable, which may include multiple wires, such as ground and signal wires. The ground wire is electrically connected to the conductive housing 221 of the SMA probe connector 220 and the signal wire is electrically connected to the signal probe 222. The reference connector 140 can be connected to the second VNA port via an RF cable. During the measurement of the electrical characteristic, the VNA transmits a signal to the SMA probe connector 220 through the first VNA port. The signal then passes through the test path and is received by the reference connector 140 with a certain magnitude. This electrical characteristic can be calculated based on the input signal transmitted to the SMA probe connector 220 and the output signal received by the reference connector 140. It can be appreciated that the VNA can also transmit a signal to the reference connector 140 through the second VNA port. The signal then passes through the test path and being received by the SMA probe connector 220 with a certain magnitude. The electrical characteristic can be calculated based on the input signal transmitted to the reference connector 140 and the output signal received by the SMA probe connector 220.

In some embodiments, the electrical characteristic can be the path loss between the SMA probe connector 220 and the reference connector 140. More specifically, the path loss can be, e.g., the impedance of the test path between the SMA probe connector 220 and the reference connector 140, which is measured by the test module.

FIG. 2 illustrates various steps of a testing method 200 for testing an electronic device according to a second embodiment of the present application.

In this embodiment, the electronic device includes a socket board, a plurality of contact pads on the socket board, and a socket unit mounted on the socket board. The plurality of contact pads include multiple ground contact pads and a signal contact pad. The socket board includes a reference connector mounted on the socket board; The socket unit includes a socket body and a plurality of contact pins vertically extending through the socket body and each being aligned with and operably connected to one of the plurality of contact pads. The testing device is operably connected to the electronic device.

As shown in FIG. 2, in step S202, a SMA probe connector is mounted on a lid body to electrically connect a conductive housing of the SMA probe connector with a conductive portion at a center of the lid body and pass a signal probe of the SMA probe connector through an opening formed at a second side of the conductive portion facing away from the plurality of contact pins and an escape groove at a first side of the conductive portion facing towards the plurality of contact pins, such that the signal probe is electrically connected with a contact pin of the socket unit aligned with the signal contact pad.

As shown in FIG. 2, in step S204, the lid body is connected to the socket unit to connect the conductive portion of the lid body with contact pins of the socket unit that are aligned with the ground contact pads, and to accommodate contact pins of the socket unit aligned with the signal contact pad to avoid contact between a contact pin and the conductive portion by the escape groove.

As shown in FIG. 2, in step S206, a first signal cable coupled to the SMA probe connector and a second signal cable coupled to the reference connector of the socket board are connected to a signal measurement instrument, to enable testing of the electronic device by the signal measurement instrument through the testing device.

In this embodiment, the structure of the electronic device and the testing device can refer to the first embodiment of the present application, which will not be repeated here. In this embodiment, the order of steps S204, and S206 can be interchanged.

The testing device is connected to the socket unit of the electronic device by the testing method of this embodiment. A conductive portion of the lid body disposed at the testing device is connected to contact pins that are aligned with ground contact pads, while the escape groove accommodates a contact pin aligned with a signal contact pad to avoid contact with the conductive portion, and a signal probe of the SMA probe connector is connected to the contact pins accommodated in the escape groove. That is, the contact pins aligned with ground contact pads are connected to ground via the conductive portion of the lid body, while a contact pin aligned with the signal contact pad is connected to the SMA probe connector. In this way, the testing device can be reliably and conveniently connected to the socket unit of the electronic device, thus improving the accuracy of testing results.

In some embodiments, the testing device further includes a positioning assembly mounted on the second side of the conductive portion which is used to adjust a distance between the lid body and the plurality of contact pins. The step of connecting the lid body to the socket unit in step S202 includes: moving the lid body toward the socket unit via the positioning assembly to connect the lid body to the socket unit.

The positioning assembly can be used to adjust a distance between the lid body and the plurality of contact pins to ensure that the conductive portion is pressed against the contact pins of the socket unit aligned with the ground contact pads, the contact pin of the socket unit aligned with the signal contact pad extends through the escape groove and makes reliable contact with the signal probe of the SMA probe connector to avoid contact with the conductive portion, and the contact pins of the socket unit aligned with one or more non-target contact pads is accommodated in the one or more additional escape groove to avoid contact with the conductive portion.

While the exemplary testing device and method for testing an electronic device of the present application is described in conjunction with corresponding figures, it will be understood by those skilled in the art that modifications and adaptations to the apparatus and method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A testing device for testing an electronic device, wherein the electronic device comprises a socket board, a plurality of contact pads on the socket board, and a socket unit mounted on the socket board; wherein the plurality of contact pads comprise multiple ground contact pads and a signal contact pad; wherein the socket unit comprises a socket body and a plurality of contact pins vertically extending through the socket body and each being aligned with and operably connected to one of the plurality of contact pads; wherein the testing device is operably connected to the electronic device, and comprises:
a lid body comprising:
a conductive portion disposed at a center of the lid body and configured to be connected to the contact pins of the socket unit that are aligned with the ground contact pads when the testing device is connected to the socket unit;
an escape groove formed at a first side of the conductive portion facing towards the plurality of contact pins, and configured to accommodate a contact pin of the socket unit aligned with the signal contact pad to avoid contact with the conductive portion when the testing device is connected to the socket unit; and
an opening formed at a second side of the conductive portion facing away from the plurality of contact pins, wherein the opening is aligned with and connected to the escape groove; and
a Sub Miniature version A (SMA) probe connector mounted on the lid body, to electrically connect a conductive housing of the SMA probe connector with the conductive portion of the lid body and extend a signal probe of the SMA probe connector through the opening and the escape groove, wherein the SMA probe connector is configured to electrically connect the signal probe with a contact pin of the socket unit aligned with the signal contact pad when the testing device is connected to the socket unit.

2. The testing device according to claim 1, wherein the plurality of contact pins comprise pogo pins.

3. The testing device according to claim 1, wherein the electronic device further comprises a reference connector mounted on the socket board and a signaling trace extending between the signal contact pad and the reference connector which are electrically coupled with each other; and wherein the testing device further comprises:
a test module configured to generate a test result by measuring an electrical characteristic associated with a test path between the reference connector and the SMA probe connector which are electrically coupled with each other by the plurality of contact pins when the testing device is connected to the socket unit.

4. The testing device according to claim 1, wherein the lid body further comprises:
a peripheral portion connected to the conductive portion, and configured to support the testing device on the socket unit when the testing device is connected to the socket unit.

5. The testing device according to claim 4, wherein the socket body comprises a sidewall at a periphery of the socket body and a cavity formed within the sidewall, and wherein the conductive portion of the lid body is received within the cavity and the peripheral portion of the lid body is supported on the sidewall of the socket body when the testing device is connected to the socket unit.

6. The testing device according to claim 5, wherein the conductive portion is chamfered at its bottom edge.

7. The testing device according to claim 1, further comprising:
a positioning assembly mounted at the second side of the conductive portion, and configured to adjust a distance between the lid body and the plurality of contact pins.

8. The testing device according to claim 7, wherein the positioning assembly is fixedly coupled to the SMA probe connector.

9. The testing device according to claim 1, wherein the plurality of contact pads of the electronic device further comprise one or more non-target contact pads,
the lid body further comprising:
one or more additional escape grooves formed at the first side of the conductive portion, and configured to accommodate contact pins of the socket unit aligned with the one or more non-target contact pads to avoid contact between the one or more non-target contact pads and the conductive portion when the testing device is connected to the socket unit.

10. A testing method for testing an electronic device, wherein the electronic device comprises a socket board, a plurality of contact pads on the socket board, and a socket unit mounted on the socket board; wherein the plurality of contact pads comprise multiple ground contact pads and a signal contact pad; wherein the socket board comprises a reference connector mounted on the socket board; wherein the socket unit comprises a socket body and a plurality of contact pins vertically extending through the socket body and each being aligned with and operably connected to one of the plurality of contact pads; wherein the testing device is operably connected to the electronic device; and wherein the method comprises:
mounting a SMA probe connector on a lid body to electrically connect a conductive housing of the SMA probe connector with a conductive portion at a center of the lid body and pass a signal probe of the SMA probe connector through an opening formed at a second side of the conductive portion facing away from the plurality of contact pins and an escape groove at a first side of the conductive portion facing towards the plurality of contact pins, such that the signal probe is electrically connected with a contact pin of the socket unit aligned with the signal contact pad;
connecting the lid body to the socket unit to connect the conductive portion of the lid body with contact pins of the socket unit that are aligned with the ground contact pads, and to accommodate contact pins of the socket unit aligned with the signal contact pad to avoid contact between a contact pin and the conductive portion by the escape groove; and
connecting a first signal cable coupled to the SMA probe connector and a second signal cable coupled to the reference connector of the socket board to a signal measurement instrument, to enable testing of the electronic device by the signal measurement instrument through the testing device.

11. The method according to claim 10, wherein the testing device further comprises a positioning assembly mounted on the second side of the conductive portion, and configured to adjust a distance between the lid body and the plurality of contact pins; and wherein connecting the lid body to the socket unit comprises:
moving the lid body toward the socket unit via the positioning assembly to connect the lid body to the socket unit.
